(19) United States
(12) Patent Application Publication
(10) Pub. No.: US 2025/0113540 A1
(43) Pub. Date: Apr. 3, 2025

(54) TRANSISTOR COMPRISING A COMPOSITE GATE DIELECTRIC STRUCTURE AND METHOD TO PROVIDE SAME

(71) Applicant: Intel Corporation, Santa Clara, CA (US)

(72) Inventors: Carl H. Naylor, Portland, OR (US); Rachel Steinhardt, Santa Clara, CA (US); Mahmut Sami Kavrik, Eugene, OR (US); Chia-Ching Lin, Portland, OR (US); Andrey Vyatskikh, Hillsboro, OR (US); Kevin O’Brien, Portland, OR (US); Kirby Maxey, Hillsboro, OR (US); Ashish Verma Penumatcha, Beaverton, OR (US); Uygar Avci, Portland, OR (US); Matthew Metz, Portland, OR (US); Chelsey Dorow, Portland, OR (US)

(73) Assignee: Intel Corporation, Santa Clara, CA (US)

(21) Appl. No.: 18/375,055

(22) Filed: Sep. 29, 2023

(51) Int. Cl. H01L 29/49; H01L 21/02; H01L 29/06; H01L 29/24; H01L 29/423; H01L 29/66; H01L 29/76; H01L 29/775; H01L 29/786

(52) U.S. Cl. CPC H10D 30/6739; H01L 21/02568; H10D 30/43; H10D 30/6735; H10D 30/6757; H10D 48/362; H10D 62/121; H10D 62/80; H10D 99/00; H10D 30/6736

(57) ABSTRACT

Techniques and mechanisms for providing gate dielectric structures of a transistor. In an embodiment, the transistor comprises a thin channel structure which comprises one or more layers of a transition metal dichalcogenide (TMD) material. The channel structure forms two surfaces on opposite respective sides thereof, wherein the surfaces extend to each of two opposing edges of the channel structure. A composite gate dielectric structure comprises first bodies of a first dielectric material, wherein the first bodies each adjoin a different respective one of the two opposing edges, and variously extend to each of the surfaces two surfaces. The composite gate dielectric structure further comprises another body of a second dielectric material other than the first dielectric material. In another embodiment, the other body adjoins one or both of the two surfaces, and extends along one or both of the two surfaces to each of the first bodies.

### BACKGROUND

### 1. Technical Field

This disclosure generally relates to the fabrication of integrated circuitry and more particularly, but not exclusively, to insulator structures of a transistor which comprises a transition metal dichalcogenide (TMD).

### 2. Background Art

Demand for integrated circuits (ICs) in portable electronic applications has motivated greater levels of semiconductor device integration. Many advanced semiconductor devices in development leverage non-silicon semiconductor materials. One class of those materials is the transition metal dichalcogenide (TMD or TMDC). Similar to graphene, TMDs display semiconductor properties as a unit cell of MX2, where M is a transition metal atom (e.g., Mo, W) and X is a chalcogen atom (S, Se, or Te). TMD materials have been of significant interest in highly-scaled integrated circuitry (IC), in part because of the thin active layers possible. TMD-channeled transistors therefore have excellent short channel properties. It has also been shown that many TMD materials have good electron and hole mobility, making them interesting for complementary short channel devices (e.g., Lg<20 nm).

Recent TMD-based transistor designs are facilitated by (for example, implemented with) one or more TMD structures each being implemented as a respective “2D material”—i.e., as a material layer, at least a substantial portion of which is not more than one molecule in thickness. However, implementation of 2D materials in field effect transistors (FETs) has proven to be a challenge, and has resulted in various complications in the formation of channels and adjoining structures of a transistor. As successive generations of transistor designs continue to decrease in scale, there is expected to be an increasing premium placed on improvements to the fabrication of a 2D material and structures proximate thereto.

### BRIEF DESCRIPTION OF THE DRAWINGS

The various embodiments of the present invention are illustrated by way of example, and not by way of limitation, in the figures of the accompanying drawings and in which:

FIG. 1 shows a flow diagram illustrating features of a method to fabricate transistor structures according to an embodiment.

FIG. 2 shows a cross-sectional view diagram illustrating features of a transistor structure comprising a composite gate dielectric structure according to an embodiment.

FIG. 3 shows a detail view diagram illustrating features of a channel structure of a transistor according to an embodiment.

FIGS. 4A through 4D are cross-sectional view diagrams each illustrating a respective stages 400 through 403 of processing to fabricate transistor structures according to an embodiment.

FIG. 5 shows a cross-sectional view diagram illustrating features of a transistor structure comprising a composite gate dielectric structure according to an embodiment.

FIGS. 6A through 6I are perspective view diagrams each illustrating a respective stage of processing to fabricate transistor structures according to an embodiment.

FIG. 7 is a cross-sectional side view of an IC structure, in accordance with some embodiments.

FIG. 8 is a functional block diagram illustrating a system which comprises a packaged IC die that includes transistor structures according to one embodiment.

FIG. 9 is a functional block diagram which illustrates an electronic computing device in accordance with some embodiments.

### DETAILED DESCRIPTION

Embodiments discussed herein variously provide techniques and mechanisms for providing gate dielectric structures which facilitate operation of a small dimension transistor. In various embodiments, a transistor comprises a thin (e.g., less than 3 nanometer) channel structure, such as a nanoribbon, nanowire, nanosheet or the like. The channel structure comprises surfaces on opposite respective sides thereof, wherein the surfaces extend to each of two opposite edges of the channel structure. For example, the channel structure comprises one or more layers of a 2D material, wherein opposing surfaces of the channel structure exhibit relatively poor nucleation site characteristics, as compared to one or more edges of said channel structure.

Some embodiments variously account for the characteristics of such edges in providing improved techniques for fabricating a gate dielectric on (e.g., around) a channel structure. In one such embodiment, gate dielectric fabrication comprises performing a first atomic layer deposition (ALD) which results in a first body, of a first dielectric material, growing from the edge of a channel structure to provide nucleation sites above a top surface (and/or below a bottom surface) of that channel structure. Such nucleation sites are available for use by a second ALD of the gate dielectric fabrication, wherein the second ALD results in a second body, of a second dielectric material, growing from the first body along that surface of the channel structure. In an embodiment, such fabrication results in the formation of a “composite” gate dielectric structure, which comprises first dielectric structures adjoining opposite respective edges of a channel structure, and which further comprises a second dielectric structure which adjoins the first dielectric structures, as well as one or more surfaces of the channel structure.

In providing techniques to fabricate a composite gate structure, some embodiments variously enable a relatively tight control of equivalent oxide thickness (EOT) characteristics of a transistor. For example, such tight control is provided by enabling a manufacturer to select a particular combination of different dielectric materials. Additionally or alternatively, such tight control is provided by enabling a manufacturer to grow on a 2D material a relatively thin dielectric material using nucleation sites which are provided with an edge-grown body of another dielectric material.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including one or more transistors each comprising a respective composite gate dielectric structure.

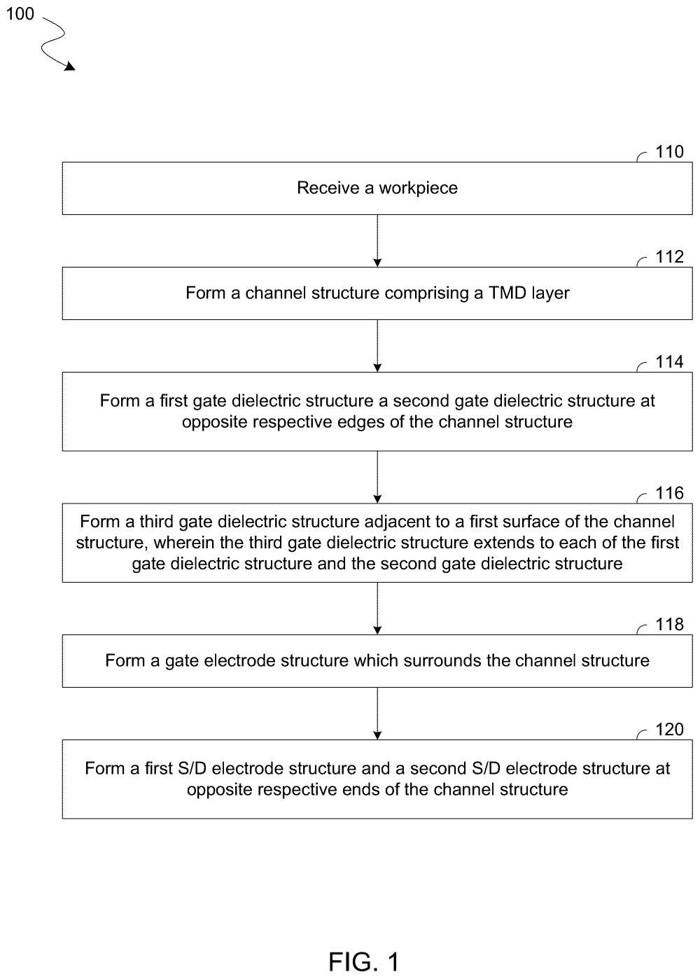

FIG. 1 shows a method 100 for fabricating transistor structures according to an embodiment. The method 100 illustrates one example of an embodiment wherein a composite gate dielectric structure is formed around a channel structure of a transistor. In an embodiment, the composite gate dielectric structure comprises dielectric bodies which variously adjoin different respective portions of the channel structure.

As shown in FIG. 1, method 100 comprises (at 110) receiving a workpiece which, for example, provides structural support for a deposition and/or other formation of various circuit structures thereon. In an embodiment, the workpiece comprises a bulk silicon substrate and, in some embodiments, a silicon on insulator (SOI) structure on the silicon substrate.

Method 100 further comprises (at 112) forming a channel structure comprising a transition metal dichalcogenide (TMD) layer. The channel structure comprises surfaces—e.g., including a first surface and a second surface—at opposite respective sides of the channel structure. As used herein in the context of a channel structure (e.g., one or more monolayers) which is formed by a TMD, “horizontal surface” (unless otherwise indicated) refers to a surface of the channel structure which exhibits relatively poor nucleation site characteristics—e.g., as compared to an edge of said channel structure.

Method 100 further comprises (at 114) forming a first gate dielectric structure and a second gate dielectric structure at opposite respective edges of the channel structure—e.g., wherein the first gate dielectric structure and the second gate dielectric structure each comprise a first dielectric material. For example, forming the first and second gate dielectric structures comprises performing a first atomic layer deposition (ALD) of the first dielectric material. In various embodiments, edges of the channel structure, as compared to first and second horizontal surfaces of the channel structure, provide a higher concentration of nucleation sites where chemical bonds can be formed between atoms of the first dielectric material and atoms of the TMD. For example, as compared to the first and second horizontal surfaces, the edges have a greater concentration of relatively weak bonds and/or TMD atoms which are available to can form additional bonds.

In various embodiments, after the first ALD, the first gate dielectric structure and/or the second gate dielectric structure extend, from a first edge or a second edge (respectively) of the channel structure, to one or each of the first horizontal surface and the second horizontal surface. In one such embodiment, the first gate dielectric structure (and/or the second gate dielectric structure) extends horizontally to partially cover one or each of the first horizontal surface or the second horizontal surface. For example, the first ALD is stopped before the first dielectric material completely covers one or each of the first and second horizontal surfaces of the channel structure.

In some embodiments, a horizontal thickness of a gate dielectric structure formed at 114 (the horizontal thickness at one of the edges of the channel structure) is greater than a vertical thickness of that gate dielectric structure from one of the horizontal surfaces of the channel structure. In this particular context, “horizontal thickness” refers to a thickness of a gate dielectric structure, as measured horizontally from an edge of a channel structure to a nearest surface of the gate dielectric structure. By way of illustration and not limitation, such a horizontal thickness is a maximum horizontal thickness of a dielectric material in a vertical cross-section of that gate dielectric structure. In another embodiment, a horizontal thickness is an average horizontal thickness of the dielectric material in such a vertical cross-section. By contrast, “vertical thickness” refers herein to a thickness of a gate dielectric structure, as measured vertically from a horizontal surface of a channel structure to a nearest surface of the gate dielectric structure. For example, such a vertical thickness is a maximum vertical thickness of a dielectric material in a vertical cross-section of that gate dielectric structure. Alternatively, a vertical thickness is an average vertical thickness of the dielectric material in such a vertical cross-section.

Method 100 further comprises (at 116) forming a third gate dielectric structure adjacent to a first horizontal surface of the channel structure. The third gate dielectric structure comprises dielectric material other than that of the first and second gate dielectric structures. For example, forming the third gate dielectric structure comprises performing a second ALD of a second dielectric material other than a first dielectric material—e.g., wherein the second dielectric material is a relatively high-k (high dielectric constant) material, as compared to the first dielectric material.

In an embodiment, the third gate dielectric structure extends to each of the first gate dielectric structure and the second gate dielectric structure. In one such embodiment, the third gate dielectric structure further adjoins the second horizontal surface—e.g., wherein the third gate dielectric structure extends along the second horizontal surface to each of the first gate dielectric structure and the second gate dielectric structure. For example, after the second ALD, the channel structure is surrounded by a combination of the first gate dielectric structure, the second gate dielectric structure, and the third gate dielectric structure—e.g., wherein the third gate dielectric structure surrounds the first and second gate dielectric structures.

Method 100 further comprises (at 118) forming a gate electrode structure which surrounds the channel structure. For example, the forming at 118 includes any of various suitable mask, pattern, deposition, planarization and/or other processes which (for example) are adapted from conventional metallization processes. In some embodiments, the gate electrode structure further surrounds each of the first gate dielectric structure, the second gate dielectric structure, and the third gate dielectric structure.

Method 100 further comprises (at 120) forming a first source or drain (S/D) electrode structure and a second S/D electrode structure at opposite respective ends of the channel structure. In an embodiment, the first and second S/D electrode structures comprise any of various suitable conductive materials to facilitate the selective conduction of a current via the channel structure, wherein the current is based on a voltage which is to be provided with the gate electrode structure. By way of illustration and not limitation, one or each of the first and second S/D electrode structures comprise any of various suitable fill metals such as, but not limited to, titanium, cobalt, tungsten, copper, or ruthenium. In some embodiments, one or each of the first and second S/D electrode structures additionally or alternatively comprise one or more contact metals including, but not limited to antimony, ruthenium, titanium, for example.

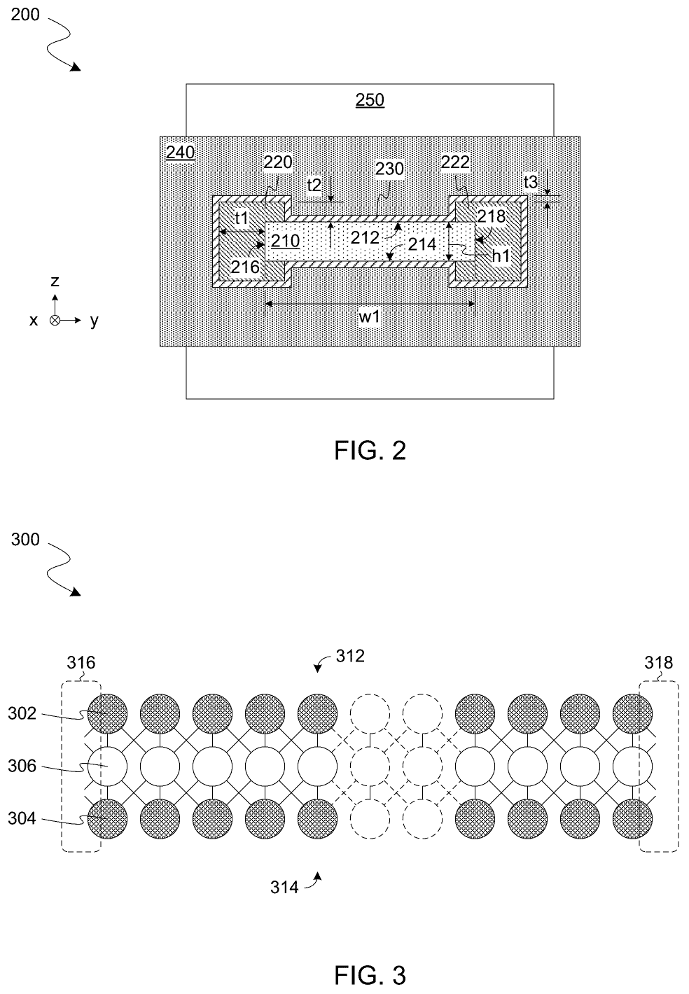

FIG. 2 shows a cross-sectional view of a transistor structure 200 which comprises composite gate dielectric structures according to an embodiment. Transistor structure 200 illustrates features of one example embodiment wherein two portions of a first dielectric material are formed on opposite edges of a channel structure, and wherein a portion of a second dielectric material extends between the two portions along a surface of the channel structure. In some embodiments, operations such as those of method 100 provide some or all of transistor structure 200.

Structures of transistor structure 200 are shown with reference to an xyz Cartesian coordinate system. Unless otherwise indicated, “length” refers herein to a dimension along the x-axis of the coordinate system, wherein “width” and “height” refer to dimension along the y-axis and the z-axis (respectively) of the coordinate system. Furthermore, unless otherwise indicated, “vertical” refers herein to a direction along a z-axis, whereas “horizontal” refers herein to a direction in an x-y plane.

As shown in FIG. 2, transistor structure 200 comprises a channel structure 210 which forms horizontal surfaces 212, 214 on opposite respective sides thereof, wherein surfaces 212, 214 each extend to opposite edges 216, 218 of channel structure 210. In an embodiment, channel structure 210 comprises a transition metal dichalcogenide (TMD) or any of various other semiconductor materials which are suitable to be deposited or otherwise formed as a 2D material. A 2D semiconductor material is a type of natural semiconductor with thicknesses on the atomic scale. For example, channel structure 210 may have a thickness that is provided by a single atomic layer of the material (i.e., a monolayer of the 2D semiconductor material). In other embodiments, the channel structure 210 may comprise several layers of the 2D semiconductor material. In a particular embodiment, the channel structure 210 may comprise van der Waals 2D materials (2D materials for short). One class of 2D materials are TMDs. TMDs are a class of two-dimensional materials, which commonly have the chemical formula MX2, where M represents any of various transition metals, such as titanium, zirconium, hafnium, vanadium, niobium, tantalum, molybdenum, tungsten, technetium, rhenium, palladium, and platinum, and X represents a chalcogen, such as sulfur, selenium or tellurium. For example, TMD semiconductors may include, but are not limited to, MoS₂, WS₂, MoSe₂, WSe₂, MoTe₂, and WTe₂. It is to be appreciated that 2D materials are not limited to the TMDs. For example, 2D materials may also include indium selenide (InSe) and graphene.

In an embodiment, channel structure 210 is formed by operations which, for example, are adapted from any of various well-known techniques for forming one or more monolayers. By way of illustration and not limitation, a given one of channel structure 210 is grown by a seed-based technique in which an initial seed material is positioned in a desired location on the surface of a sacrificial layer (not shown), and a single-crystal 2D material, with no grain boundaries, is grown with the seed material as a template. Subsequently, the sacrificial layer is removed to expose one or more horizontal surfaces of the 2D material.

In another example, a given one of channel structure 210 is grown by metal organic chemical vapor deposition (MOCVD). When a 2D layer is formed by MOCVD, the resulting material may not be single-crystal, but may have grains therein. In some embodiments, the grain sizes of channel structure 210 formed by MOCVD may be less than 5 microns (e.g., between 200 nanometers and 1 micron, between 200 nanometers and 5 microns, or between 1 micron and 5 microns). In other embodiments, other epitaxial techniques, such as molecular beam epitaxy (MBE) may be used. In still other embodiments, a 2D material is transferred from another substrate which is more suitable for growth of a TMD material.

In an embodiment, transistor structure 200 further comprises a composite gate dielectric structure which extends around channel structure 210. The composite gate dielectric structure comprises gate dielectric structures 220, 222 which each comprise a first dielectric material, wherein gate dielectric structures 220, 222 adjoin edges 216, 218 (respectively) of channel structure 210. In one illustrative embodiment, the first dielectric material is deposited by an ALD process to form gate dielectric structures 220, 222, which (for example) variously extend each to surface 212 and/or each to surface 214. In some embodiments, gate dielectric structures 220, 222 each extend vertically past surface 212 (and/or past surface 214) to provide respective sites from which one or more other dielectric structures can be grown along surface 212 and/or along surface 214.

For example, in the embodiment shown, the composite gate dielectric structure further comprises another gate dielectric structure 230 which comprises a second dielectric material other than the first dielectric material. Gate dielectric structure 230 extends horizontally along surface 212 to each of gate dielectric structures 220, 222 and/or extends horizontally along surface 214 to each of gate dielectric structures 220, 222. In one illustrative embodiment, the second dielectric material is deposited by another ALD process to form gate dielectric structure 230. For example, the second dielectric material nucleates off of surfaces of gate dielectric structures 220, 222 and grows along one or each of surfaces 212, 214.

In some embodiments, a given one of the first dielectric material or the second dielectric material is a high-k material having a bulk relative permittivity over 7 (e.g., 8, or more). A high-k gate material may have any composition known to be suitable as a gate dielectric, such as, but not limited to, metal oxides or metal silicates. In some examples, a given one of the first dielectric material or the second dielectric material comprises oxygen and at least one of Hf (e.g., HfO₂), Al (e.g., Al₂O₃), Zr (e.g., ZrO₂), Y (e.g., Y₂O₃), Ta (e.g., Ta₂O₅), or Ti (e.g., TiO₂). Silicates, such as, but not limited to HfSiOₓ, or TaSiOₓ may also be suitable. Additionally or alternatively, one of the first dielectric material or the second dielectric material includes a lower-k material, for example having a bulk relative permittivity of 7, or less. Lower-k gate material may have any composition known to be suitable as a gate dielectric, such as, but not limited to, silicon dioxide, silicon nitride, or silicon oxynitride. Hence, in some embodiments, one of the first dielectric material or the second dielectric material is either a high-k metal oxide or lower-k native oxide (for example)—e.g., wherein a dielectric constant of the first dielectric material is less than a dielectric constant of the second dielectric material.

In an embodiment, transistor structure 200 further comprises a gate electrode structure 240 which extends around channel structure 210 and the composite gate dielectric structure—e.g., wherein gate dielectric structures 220, 222 and gate dielectric structure 230 are variously between channel structure 210 and gate electrode structure 240. By way of illustration and not limitation, channel structure 210 is supported at least in part by a source or drain (S/D) electrode structure 250—e.g., wherein channel structure 210, gate electrode structure 240 and the composite gate dielectric variously extend between S/D electrode structure 250 and another S/D electrode structure (not shown) of transistor structure 200.

Gate electrode structure 240 illustrates a body of any of various materials which are suitable to provide functionality of a gate electrode. For example, in some embodiments, such a body comprises a doped semiconductor and/or an elemental metal layer, a metal alloy layer, or a laminate structure of either or both. In some embodiments, gate electrode structure 240 comprises a metal nitride, such as TiN (e.g., having a work function in a range of 4.0-4.7 eV). For example, gate electrode structure 240 comprises one of titanium, aluminum, or nitrogen (for example)—e.g., wherein a stoichiometry of a conductive material of gate electrode structure 240 is substantially the same as that of one of TiN or TiAlN. However, other alloy constituents may be additionally or alternatively employed in gate electrode structure 240—e.g., including, but not limited to, C, Ta, W, Pt, or Sn. In some embodiments, a conductor of gate electrode structure 240 has a work function which is suitable to facilitate a desired channel threshold voltage (Vₜ) as a function of the composition of channel structure 210. In one such embodiment, gate electrode structure 240 advantageously has a work function below 5 eV. In an embodiment, the work function to provide with gate electrode structure 240 depends on a 2D material type (e.g., n-type vs p-type). For example, for a p-type 2D material, it is typical to have a work function above 5 eV, whereas an n-type 2D material usually operates with a lower work function.

In various embodiments, dimensions of the composite gate dielectric structure facilitate a selective conduction of current by channel structure 210 based on a voltage which is to be provided with gate electrode structure 240. In an illustrative scenario according to one embodiment, a width w1 of the channel structure 210 (between the edges 216, 218) is in a range of 5 nanometers (nm) to 10 nm—e.g., wherein a height h1 of channel structure 210 is in a range of 0.5 nm to 3 nm. In one such embodiment, a horizontal thickness t1 of one of gate dielectric structures 220, 222 (e.g., from the edge 216 of channel structure 210 to a nearest surface of gate dielectric structure 220) is in a range of 4 nm to 8 nm. By contrast, a vertical thickness t2 of that one of gate dielectric structures 220, 222 (e.g., from the surface 212 of channel structure 210 to a nearest surface of gate dielectric structure 220) is in a range of 1 nm to 4 nm. In some embodiments, a ratio Rvh of the vertical thickness t2 to the horizontal thickness t1 is in a range of 0.25 to 0.75. Additionally or alternatively, a thickness t3 of gate dielectric structure 230 is in a range of 0.5 to 3 nm, for example. However, such dimensions and/or ratios are merely illustrative of some embodiments, and are not limiting of other embodiments.

FIG. 3 shows a detail view of a channel structure of a transistor according to an embodiment. Channel structure 300 illustrates one example embodiment wherein opposing surfaces of a 2D material substantially extend in respective first (e.g., horizontal) planes, wherein edges of the 2D material variously extend vertically between the opposite surfaces. Due to its chemical structure, the 2D material has relatively low reactivity on each of the opposing surfaces, as compared to a reactivity which the 2D material has at the various edges. In some embodiments, channel structure provides functionality such as that of channel structure 210—e.g., wherein operations of method 100 provide structures of a transistor which includes channel structure 300.

In the illustrative embodiment, a TMD material of channel structure 300 includes a layer of a transition metal 306 between a layer of chalcogen atoms 302 and a layer of chalcogen atoms 304, as shown. Depending on arrangements of the atoms, the structures of TMDs can have various crystal orientations, such as trigonal prismatic (hexagonal), octahedral (tetragonal, T) or their distorted phase (TO). In the illustrative embodiment, the TMD material is hexagonal. The monolayer of TMD, such as that shown, has a thickness of approximately 0.7 nm, for example. The transition metal includes molybdenum, tungsten or chromium, and the chalcogen includes at least one of sulfur, selenium or tellurium. TMD materials described above advantageously provide channel mobility as high as 700 cm² V⁻¹ s⁻¹.

In the example embodiment shown, the layer of chalcogen atoms 302 and the layer of chalcogen atoms 304 form opposing surfaces 312, 314 (respectively) of a TMD monolayer. As compared to surfaces 312, 314, edges 316, 318 of the TMD monolayer have a relatively high concentration of weak bonds and/or sites where chemical bonding can take place. As a result, edges 316, 318 are relatively well suited—as compared to surfaces 312, 314—to facilitate the nucleation of a dielectric material thereon.

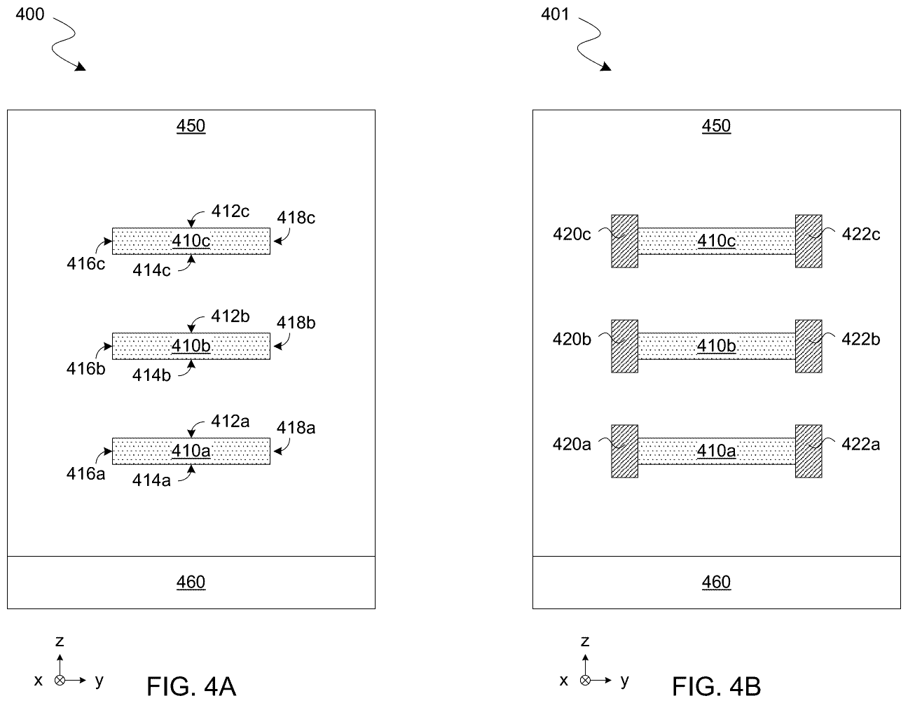

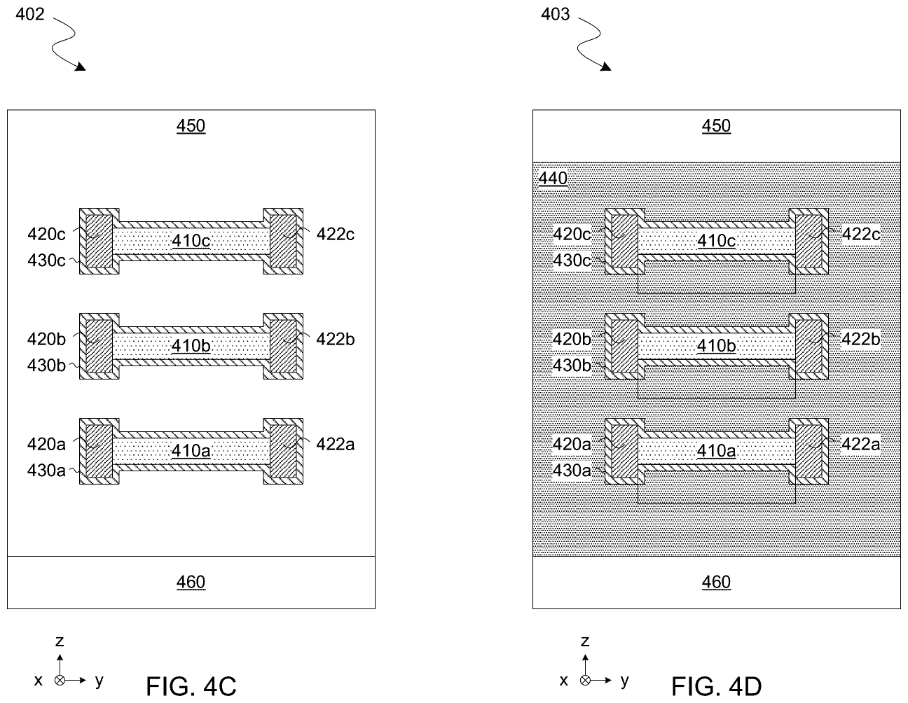

FIGS. 4A through 4D show respective stages 400 through 403 of processing to fabricate transistor structures comprising a composite gate dielectric according to an embodiment. The stages 400 through 403 illustrate one example of an embodiment which forms a composite gate dielectric structure around a 2D material of a channel structure. In various embodiments, processing such as that illustrated by stages 400 through 403 provides circuit structures such as those of transistor structure 200—e.g., wherein said processing includes operations of method 100.

At the stage 400 shown in FIG. 4A, a substrate structure 460 has formed thereon a support structure 450 and multiple channel structures—such as the illustrative channel structures 410a-c shown—which are variously arranged in a vertical configuration with each other over substrate structure 460. In an embodiment, the substrate structure 460 includes a suitable semiconductor material such as but not limited to, single crystal silicon, polycrystalline silicon and silicon on insulator (SOI) material, where a trilayer stack includes a layer of silicon oxide between two layers of monocrystalline silicon. In another embodiment, substrate structure 460 includes other semiconductor materials such as germanium, silicon germanium or a suitable group III-N or a group III-V compound.

Support structure 450 represents any of various structures which provide at least partial structural support for the vertically arranged channel structures 410a-c. In an illustrative scenario according to one embodiment, support structure 450 comprises a spacer structure which is to provide electrical insulation between a gate electrode (not shown) of a transistor and a S/D structure (not shown) of the transistor. Alternatively or in addition, the support structure 450 comprises the S/D structure (for example). In some embodiments, the support structure 450 additionally or alternatively comprises a sacrificial material (such as any of various suitable dielectric materials) which are to be subsequently etched or otherwise removed, at least in part, e.g., to accommodate a later fabrication of a S/D structure.

In the example embodiment shown, channel structure 410a forms horizontal surfaces 412a, 414a which variously extend to each of opposite edges 416a, 418a of channel structure 410a. Furthermore, channel structure 410b forms horizontal surfaces 412b, 414b which variously extend to each of opposite edges 416b, 418b of channel structure 410b. Further still, channel structure 410c forms horizontal surfaces 412c, 414c which variously extend to each of opposite edges 416c, 418c of channel structure 410c.

In various embodiments, channel structures 410a-c variously provide functionality such as that of channel structure 210—e.g., wherein the processing illustrated by stages 400 through 403-403 is to provide structures of a multi-channel transistor. For example, channel structures 410a-c each comprise a respective one or more layers of a 2D material such as a TMD material. In one such embodiment, horizontal surfaces 412a-c, and horizontal surfaces 414a-c exhibit relatively poor nucleation site characteristics, as compared to edges 416a-c, edges 418a-c.

Referring now to FIG. 4B, at stage 401 a first dielectric material has been deposited—e.g., by a first ALD process—to variously form first gate dielectric structures each on a respective one of the edges 416a-c, 418a-c channel structures 410a-c. More particularly, gate dielectric structures 420a, 422a are formed on the opposing edges 416a, 418a (respectively) of channel structure 410a. Furthermore, gate dielectric structures 420b, 422b are formed on the opposing edges 416b, 418b (respectively) of channel structure 410b—e.g., wherein gate dielectric structures 420c, 422c are formed on the opposing edges 416c, 418c (respectively) of channel structure 410c. The first ALD process is stopped before horizontal surfaces 412a-c, 414a-c are completely covered by the first dielectric material. In an embodiment, gate dielectric structures 420a-c each correspond functionally to gate dielectric structure 220—e.g., wherein gate dielectric structures 422a-c each correspond functionally to gate dielectric structure 222.

At the stage 402 shown in FIG. 4C, a second dielectric material has been deposited—e.g., by a second ALD process—to variously form second gate dielectric structures each on a respective horizontal surface of channel structures 410a-c. For example, a gate dielectric structure 430a is formed on one or both of surfaces 412a, 414a—e.g., wherein gate dielectric structure 430a further extends around gate dielectric structures 420a, 422a. Furthermore, another gate dielectric structure 430b is formed on one or both of surfaces 412b, 414b—e.g., wherein gate dielectric structure 430b further extends around gate dielectric structures 420b, 422b. Further still, another gate dielectric structure 430c is formed on one or both of surfaces 412c, 414c—e.g., wherein gate dielectric structure 430c further extends around gate dielectric structures 420c, 422c.

In the example embodiment shown, gate dielectric structure 430a surrounds channel structure 410a and gate dielectric structures 420a, 422a—e.g., wherein gate dielectric structure 430b surrounds channel structure 410b and gate dielectric structures 420b, 422b, and wherein gate dielectric structure 430c surrounds channel structure 410c and gate dielectric structures 420c, 422c. In one such embodiment, gate dielectric structures 430a-c variously provide functionally such as that of gate dielectric structure 230.

At the stage 403 shown in FIG. 4D, a gate electrode structure 440 has been deposited on substrate structure 460 and around channel structures 410a-c—e.g., wherein gate dielectric structures 430a-c are variously between channel structures 410a-c (respectively) and gate electrode structure 440. Gate electrode structure 440 illustrates a body of any of various materials which are suitable to provide functionality of a gate electrode—e.g., wherein gate electrode structure 440 includes one or more features of gate electrode structure 240.

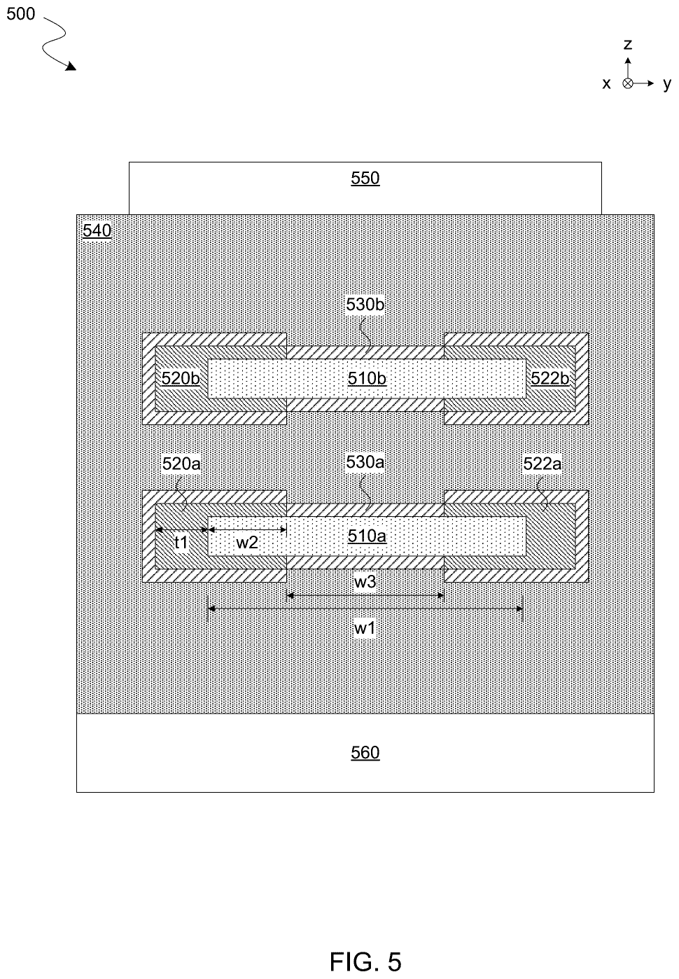

FIG. 5 shows a cross-sectional view of a transistor structure 500 which comprises composite gate dielectric structures according to an embodiment. Transistor structure 500 illustrates features of one example embodiment wherein a composite gate dielectric includes a first bodies of a first dielectric material, wherein the first bodies each adjoins a different respective edge of a channel structure, and each extend partially along a horizontal surface of the channel structure. The composite gate dielectric further includes a second body of a second dielectric material, wherein the second body adjoins the horizontal surface and extends between, and to each of, the first bodies. In some embodiments, transistor structure 500 provides functionality such as that of transistor structure 200—e.g., wherein method 100 (or processing such as that illustrated by stages 400-403, for example) is performed to provide some or all of transistor structure 500.

As show in FIG. 5, transistor structure 500 comprises a substrate structure 560 which has formed thereon a support structure 550 and multiple channel structures-such as the illustrative channel structures 510a, 510b shown—which are variously arranged in a vertical configuration with each other over substrate structure 560. In an embodiment, the substrate structure 560 includes a bulk semiconductor substrate and, for example, a SOI structure thereon—e.g., wherein S/D electrode structure 550 and support structure 560 correspond functionally to support structure 450 and substrate structure 460 (respectively). Support structure 550 represents any of various structures which provide at least partial structural support for the vertically arranged channel structures 510a, 510b—e.g., wherein channel structures 510a, 510b variously provide functionality such as that of one of channel structures 210, 300, 410a-c.

In an embodiment, transistor structure 500 further comprises a first composite gate dielectric structure and a second composite gate dielectric structure which extend around channel structure 510a, and channel structure 510b (respectively). For example, the first composite gate dielectric structure comprises gate dielectric structures 520a, 522a which adjoin opposing edges of channel structure 510a. In one such embodiment, the first composite gate dielectric structure further comprises a gate dielectric structure 530 which extends along, and adjoins, one or each of the top and bottom horizontal surfaces of channel structure 510a.

In an embodiment, gate dielectric structures 520a, 522a further extend partially along the top and bottom horizontal surfaces of channel structure 510a, wherein at least some of gate dielectric structure 530a extends between (and adjoins) gate dielectric structures 520a, 522a on a horizontal surface of channel structure 510a. By way of illustration and not limitation, a portion of gate dielectric structure 520a which extends over a top surface (or under a bottom surface) of channel structure 510a has a width w2 that, for example, is between 5% and 30% of a width w1 of channel structure 510a. For example, the width w2 is greater than a horizontal thickness t1 of gate dielectric structure 520a. In one such embodiment, a portion a top surface (or a bottom surface) of channel structure 510 which is not covered by gate dielectric structures 520a, 522a has a width w3 which is between 40% and 90% of the width w1.

Similarly, the second composite gate dielectric structure comprises gate dielectric structures 520b, 522b which adjoin opposing edges of channel structure 510b. In one such embodiment, the second composite gate dielectric structure further comprises a gate dielectric structure 530 which extends along, and adjoins, one or each of the top and bottom horizontal surfaces of channel structure 510b. In an embodiment, gate dielectric structures 520b, 522b further extend partially along the top and bottom horizontal surfaces of channel structure 510b, wherein at least some of gate dielectric structure 530b extends between (and adjoins) gate dielectric structures 520b, 522b on a horizontal surface of channel structure 510b.

In an embodiment, transistor structure 500 further comprises a gate electrode structure 540 which extends around channel structures 510a, 510b, and also around the first and second composite gate dielectric structures. In one such embodiment, gate electrode structure 540 provides functionality such as that of gate electrode structure 240 or gate electrode structure 440 (for example).

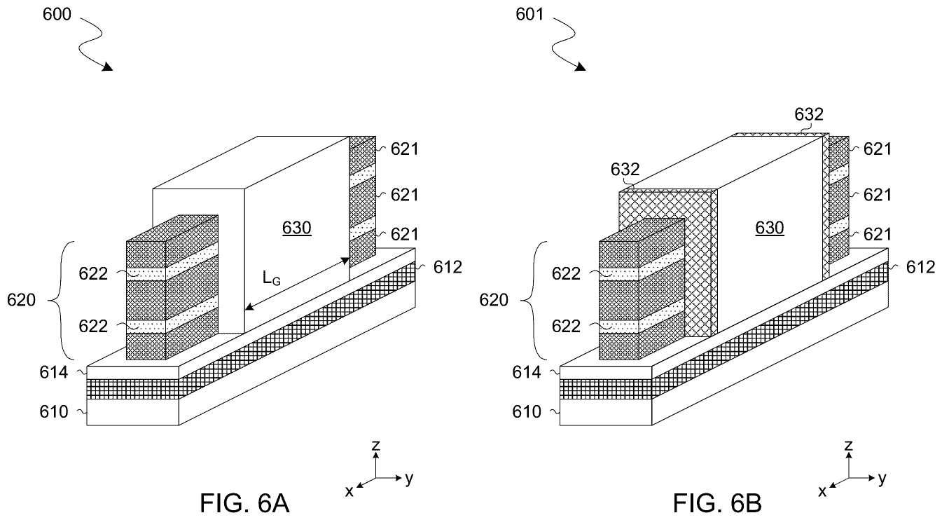

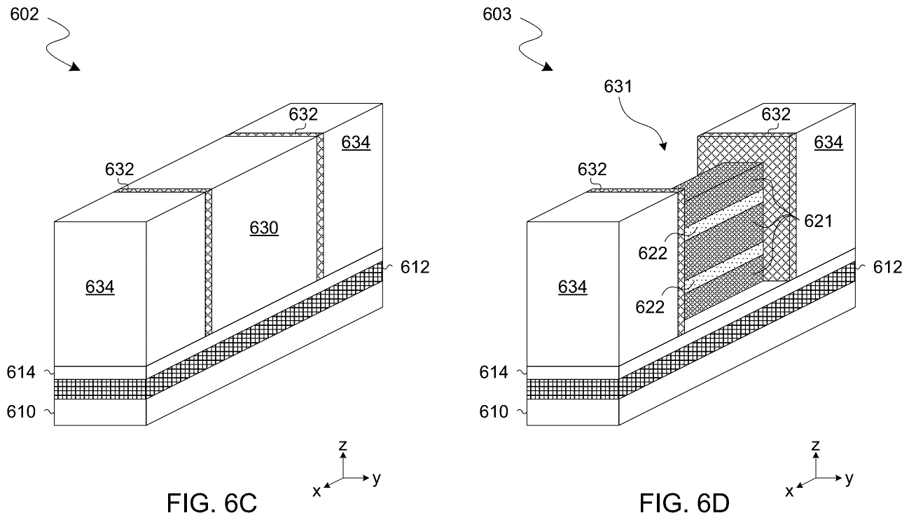

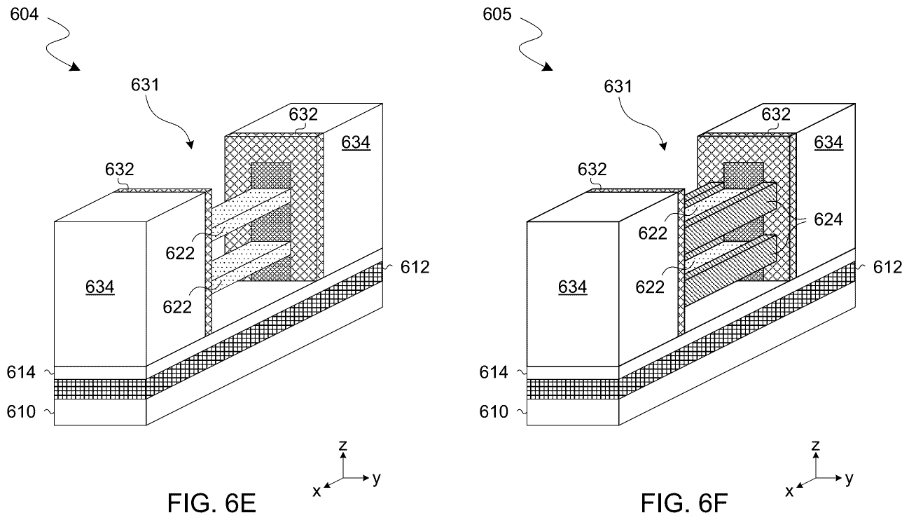

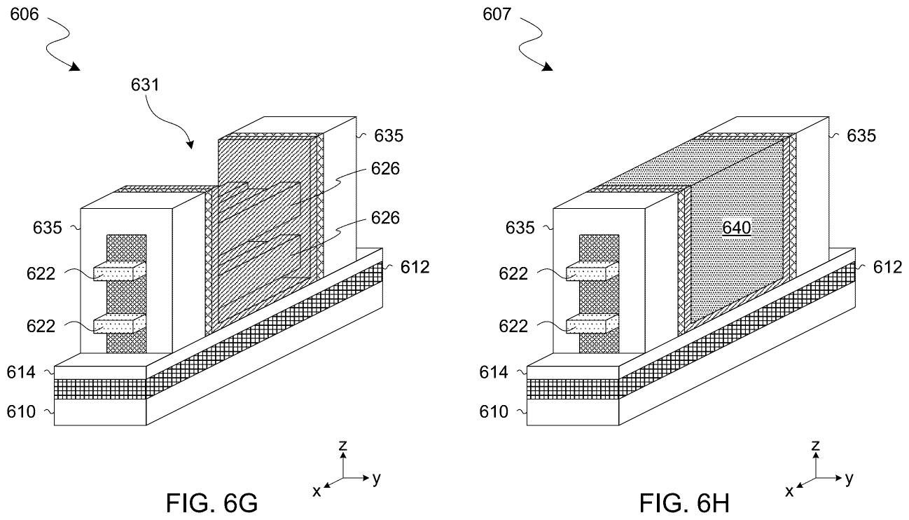

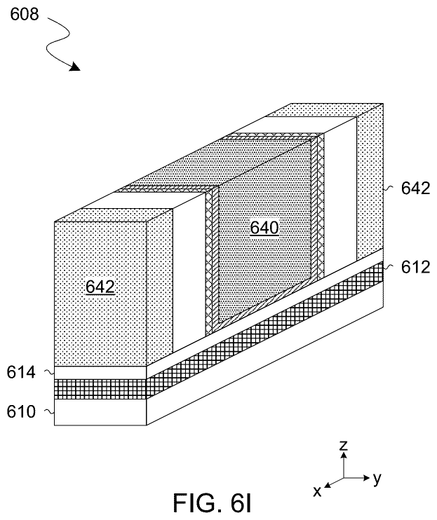

FIGS. 6A through 6I show respective stages 600 through 608 of processing to fabricate transistor structures comprising according to an embodiment. The stages 600 through 608 illustrate one example of an embodiment which forms one or more composite gate dielectric structures each around a different respective channel structure of a transistor. In various embodiments, processing such as that illustrated by stages 600 through 608 provides some or all of transistor structure 200, or transistor structure 500—e.g., wherein said processing includes operations of method 100, and/or features of the processing illustrated by stages 400 through 403.

At the stage 600 shown in FIG. 6A, a silicon substrate 610 has formed thereon a buffer layer 612 which, for example, is to overcome lattice and thermal mismatch between the substrate 610 and one or more group III-N (and/or other) semiconductor materials to be formed above. The buffer layer 612 may be grown on the substrate 610 by a metal organic chemical vapor deposition (MOCVD) process at a temperature in the range of 1000-1100 degrees Celsius. Depending on embodiments, the buffer layer 612 includes nitrogen and one or more of, Al, In or Ga, for example Al_{z}Ga_{1-z}N, Al_{w}In_{1-w}N, or AlN, for example. In exemplary embodiments buffer layer 612 includes AlN. In an embodiment, an AlN buffer layer 612 has a hexagonal wurtzite structure. The buffer layer 612 including AlN is grown to a thickness between 25 nm and 100 nm, in one example, embodiment. In other embodiments, the buffer layer 612 includes a plurality of layers of III-N materials above the substrate 610. The layers may be interleaved with two or more layers of III-N materials such as but not limited to Al_{z}Ga_{1-z}N, Al_{w}In_{1-w}N, or AlN.

A template layer 614 is formed on the buffer layer 612. In an embodiment, the template layer 614 is formed by an MOVCD epitaxy process. The template layer 614 is deposited to a thickness between 10 nm and 50 nm, for example. In one example embodiment, the template layer 614 is a layer of GaN. In an embodiment, the GaN-template layer 614 is grown to a thickness that is between 100 nm and 400 nm. A GaN-template layer 614 may have a defect density less than (1e10/cm²) when grown to a thickness of at least 100 nm.

In an embodiment, a patterned stack structure 620 is formed on template layer 614—e.g., by patterning a stack of material layers which are successively formed on template layer 614. In one such embodiment, the material layer stack comprises first layers, each of a respective TMD material, and second layers each of a respective sacrificial material which are alternating with the TMD layers. In an embodiment, a plasma etch process may be utilized to form the patterned stack structure 620 from the material layer stack. In exemplary embodiments, sidewalls of patterned stack structure 620 are substantially vertical as shown. The patterning process carried out etches the lowermost sacrificial layer directly adjacent to template layer 614—e.g., wherein the etch process is halted after exposure of the template layer 614.

In the example embodiment shown, patterned stack structure 620 comprises patterned layers 622 which each comprise a respective TMD material—e.g., wherein a given one of TMD layers 622 is a monolayer structure. In one such embodiment, other patterned layers 621 of patterned stack structure 620 are interleaved with TMD layers 622, wherein layers 621 comprise any of various materials which are suitable to facilitate structural support for TMD layers 622, and which are also suitable to accommodate, as a sacrificial material, any of various subtractive processes (a selective wet etch process, for example) which are selective of the TMD material(s) of layers 622. In one example embodiment, the layers 621 include a group III-N material. In an exemplary embodiment, layer 621 include nitrogen and one or more of Al or In. In an exemplary embodiment, layers 621 include AlN. An AlN layers 621 can be grown by MOCVD epitaxially on the template layer 614 and provides a surface for graphoepitaxy growth of the TMD layers 622.

In embodiments where the AlN layers 621 is single crystalline, templating TMD layers 622 off AlN layers 621 facilitates optimizing grain size of the TMD layers 622. The layers 621 also provide sufficiently high etch selectivity (greater than 5:1) relative to the template layer 614. The AlN layers 621 is grown to a thickness between 6 nm and 8 nm, for example.

The TMD layers 622 are formed in an alternating arrangement with layers 621, where TMD layers 622 includes a material such as that of channel structure 210, channel structure 300, channel structures 410, channel structures 510, or the like. Depending on embodiments, a given one of TMD layers 622 has a vertical (z-axis) thickness that is in a range of one to four monolayers, for example. In one illustrative embodiment, a given one of TMD layers 622 includes at least 3 monolayers. The TMD layers 622 are formed by an MOCVD or a CVD process, for example.

Various ones of layers 621 are epitaxially formed each on a different respective one of TMD layers 622. The respective vertical (z-axis) thickness of some or all of layers 621 are different, in some embodiments. A given one of TMD layers 622 may or may not include a same material, and/or a same number of monolayers, as that of another of TMD layers 622. In an exemplary embodiment, the TMD layers 622 are substantially the same, i.e., they both include a same material and have a same number of monolayers, as is shown in FIG. 6A. The patterned stack structure 620 includes an additional layer 621 formed on a top one of TMD layers 622. While two TMD layers 622 are shown, the number of TMD layers can be between two and ten, in some embodiments.

At stage 600, a dummy gate structure 630 is formed on a portion of the patterned stack structure 620. In an embodiment, a dummy gate material is blanket deposited on the patterned stack structure 620 and on the template layer 614. In an embodiment, a mask is formed on the dummy gate material and a plasma etch process is utilized to pattern the dummy gate material into dummy gate structure 630, selective to an uppermost surface 118A of the template layer 614, as shown. In an embodiment, the dummy gate structure 630 has sidewalls that are substantially vertical relative to an uppermost surface of template layer 614. The dummy gate structure 630 has a lateral length, L_{G} which, for example, determines at least in part a length of a transistor gate that is to be subsequently formed.

Referring now to FIG. 6B, at stage 601 dielectric spacers 632 are formed adjacent to opposite respective sides of the dummy gate structure 630. In an embodiment, a given dielectric spacer layer 632 is blanket deposited on the patterned stack structure 620 and on the dummy gate structure 630. The deposition process utilized may include a PECVD (plasma enhanced chemical vapor deposition), physical vapor deposition (PVD), chemical vapor deposition (CVD) process. In an embodiment, the dielectric spacers 632 include silicon and nitrogen and/or carbon.

In an embodiment, a patterned mask (not shown) is formed over the dummy gate structure 630 and over a portion of a deposited dielectric spacer material. Subsequently, the dielectric spacer material is etched, through the patterned mask, to form dielectric spacer 632. A plasma etch may be utilized to pattern the dielectric spacer 632. An over etch of the dielectric spacer layer is carried out to remove the dielectric spacer layer from sidewall portions of the patterned stack structure 620 that are not covered by the mask. In the illustrative embodiment, the etch is selective to the material of the uppermost surface of template layer 614. Additionally or alternatively, the dielectric material of dielectric spacers 632 is planarized. The planarization process may expose an uppermost surface of the dummy gate structure 630.

In the illustrative embodiment, the dielectric spacer 632 is formed on sidewall portions of the patterned stack structure 620 directly adjacent to the dummy gate structure 630. As shown, the dummy gate structure 630 and the dielectric spacer 632 both cover portions of the sidewalls of the patterned stack structure 620. The dielectric spacer 632 may be formed to a thickness that is determined by downstream process, electrical performance (such as modulating external resistance) or a combination thereof. In an embodiment, a given one of dielectric spacers 632 has a length (x-axis) between 5 nm to 10 nm.

At the stage 602 shown in FIG. 6C, another dielectric material is deposited on the exposed portions of the patterned stack structure 620 (not visible), on the dielectric spacer 632, and (in some embodiments) on uppermost surface of the dummy gate structure 630. In an embodiment, the dielectric material is deposited by a blanket deposited using a physical vapor deposition (PVD) or a chemical vapor deposition (CVD) process. In one such embodiment, a chemical mechanical polish (CMP) process is utilized to planarize the dielectric material to form dielectric structures 634 which are each adjacent to a different respective one of the dielectric spacers 632 on opposite respective sides of the dummy gate structure 630. In an embodiment, respective uppermost surfaces of dielectric spacers 632, and dielectric structures 634 are substantially co-planar with an uppermost surface of the dummy gate structure 630.

At the stage 603 shown in FIG. 6D, dummy gate structure 630 (not shown) is etched or otherwise removed to expose respective portions of the layers 621 and the isolate TMD layers 622. In an embodiment, where the dummy gate structure 630 includes a material such as polysilicon, silicon germanium, germanium, a combination of plasma etch and wet chemical etch can be utilized to remove the dummy gate structure 630. Removal of the dummy gate structure 630 forms an opening 631 as illustrated. In an embodiment, removal of the dummy gate structure 630 does not appreciably alter the lateral width of the dielectric spacers 632.

Referring now to FIG. 6E, at stage 604, exposed portions of the layers 621 are selectively removed after formation of opening 631. The extent of lateral etching (along the x-z plane) of layers 621 may depend on the method utilized to etch. In an embodiment, a wet chemical process is utilized. The wet etch chemistry may selectively etch layers 621 with respect to TMD layers 622, dielectric spacer 632, template layer 614 and dielectric structures 634. The process of removing exposed portions of the sacrificial layers 621 forms suspended portions of TMD layers 622 as shown.

In an embodiment, the wet etch process etches the layers 621 in the opening 631 but not under the dielectric spacers 632. As shown in FIG. 6E, remaining portions of the sacrificial layers 621 are substantially aligned with the sidewalls of dielectric spacers 632 which adjoin opening 631.

In some other embodiments, remaining portions of layers 621 (not shown in FIG. 6E) are completely removed under the dielectric spacers 632—e.g., wherein some or all such remaining portions are partially recessed under dielectric spacers 632. In one such embodiment, remaining portions of layers 621 have curved sidewall profiles which are indicative of the etch process which formed opening 631.

At the stage 605 shown in FIG. 6F, gate dielectric structures 624 are variously formed each at a respective edge of a corresponding one of TMD layers 622. In various embodiments, gate dielectric structures 624 are formed by an atomic layer deposition (ALD) process, wherein the various edges of layers 622 provide nucleation sites from which gate dielectric structures 624 are variously grown. For a given one of the TMD layers 622, two of the gate dielectric structures 624 grow each from a different respective edge of said layer—e.g., wherein two of the gate dielectric structures 624 further grow past (and in some embodiments, partially around) the top and bottom surfaces of said layer. However, growth of gate dielectric structures 624 is stopped before the respective top surfaces and bottom surfaces of layers 622 are completely covered. In various embodiments, a given one of gate dielectric structures 624 has some or all of the features of one of gate dielectric structure 220, 222, 420a-c, 422a-c, 520a-b, 522a-b (for example). Although not shown, in some embodiments, the dielectric material of gate dielectric structures 624 is further deposited on one or more surfaces of dielectric spacers 632 or on the exposed surface of template layer 614.

At the stage 606 shown in FIG. 6G, gate dielectric structures 626 are variously formed each along the exposed surfaces of a respective one of TMD layers 622. In an embodiment, the gate dielectric structures 626 are further formed each over a respective two of the gate dielectric structures 624. In various embodiments, gate dielectric structures 626 are formed by an ALD process, wherein respective edges and/or other surfaces of gate dielectric structures 624 provide nucleation sites from which gate dielectric structures 626 are variously grown. In various embodiments, a given one of gate dielectric structures 626 has some or all of the features of one of gate dielectric structures 230, 430a-c, 530a-b (for example). Although some embodiments are not limited in this regard, the dielectric material of gate dielectric structures 626 is further deposited on one or more surfaces of dielectric spacers 632 and/or on the top surface of template layer 614.

In the illustrative embodiment shown, a plasma etch, wet etch, vapor etch and/or other suitable processes remove portions of dielectric structures 634 to expose respective end portions of the TMD layers 622. In one such embodiment, etch processes further remove end portions of sacrificial layers 621, thereby exposing end portions of the respective top and bottom surfaces of TMD layers 622. Such etch processing is performed, for example, while a patterned mask (not shown) protects the structures in opening 631.

At the stage 607 shown in FIG. 6H, metal deposition processing—performed after the formation of gate dielectric structures 624, 626 in the opening 631—has formed a gate electrode structure 640 which extends around and between gate dielectric structures 626. Furthermore, gate electrode structure 640 variously extends around each of gate dielectric structures 624 (and, accordingly, around and between layers 622).

After formation of the gate dielectric structures 626, one or more layers of gate electrode material is blanket deposited in the opening 631, on the gate dielectric structures 626. After such deposition, the one or more layers of gate electrode material may be planarized. In an embodiment, the planarization process is utilized to remove any excess gate electrode material and gate dielectric structures 626 from uppermost surfaces of the dielectric structures 634, and dielectric spacers 632. The planarization process forms a gate electrode structure 640.

At the stage 608 shown in FIG. 6I, source or drain (S/D) electrode structures 642 are formed at opposite respective ends of the TMD layers 622. In an embodiment, one or more layers of electrode material are blanket deposited on exposed surfaces of gate dielectric structures 626 and (for example) on uppermost surfaces of dielectric spacers 632, gate electrode structure 640, and/or remaining portions of dielectric structures 634. In an embodiment, a planarization process is utilized to remove an excess of the one or more layers of electrode material, where such planarization forms S/D electrode structures 642.

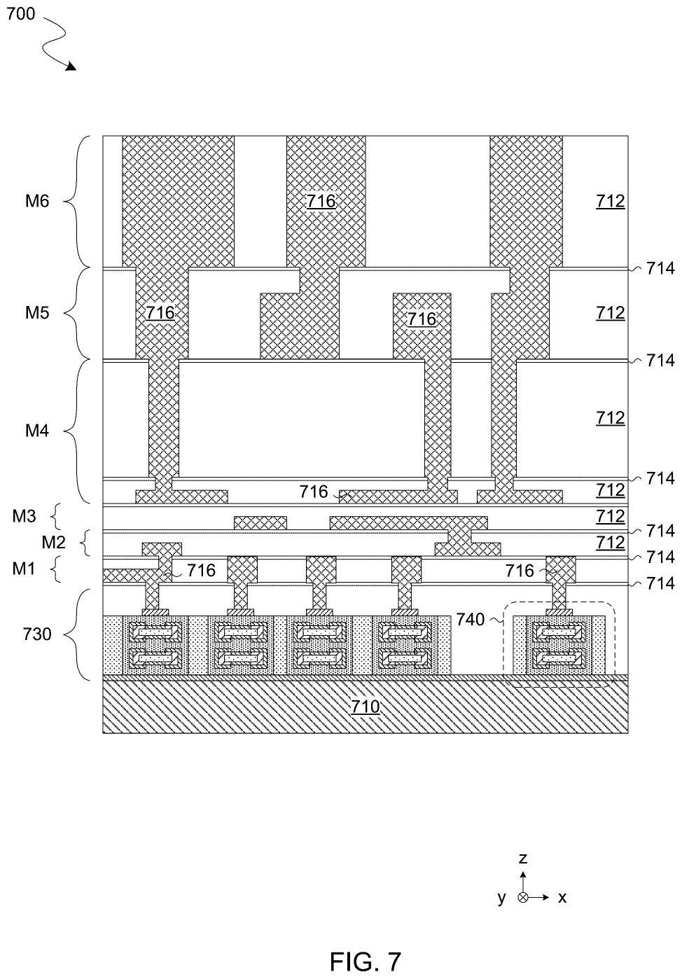

FIG. 7 illustrates a cross-sectional side view of an integrated circuit (IC) device 700 which comprises one or more transistors in accordance with some embodiments. IC device 700 illustrates a portion of a monolithic IC that includes front end of line (FEOL) circuit structures that are over and/or on a monocrystalline substrate 710. IC device 700 further includes back end of line (BEOL) circuit structures that are over and/or on the FEOL circuit structures. In an illustrative scenario according to one embodiment, the FEOL circuit structures comprise a transistor structure 740 which (for example) includes some or all of the features of the transistor shown in FIG. 2.

In the illustrated example, FEOL circuit structures include a plurality of field effect transistors (FETs) 730, one or more of which—such as the illustrative transistor structure 740 shown—each employs a respective TMD layer structure for at least a respective channel region of the transistor. Although some embodiments are not limited in this regard, the FEOL circuit structures further include any of various other types of transistors (e.g., bipolar junction transistor, etc.), and/or other active devices employing one or more semiconductor materials (e.g., diodes, lasers, etc.).

In the example embodiment shown, a channel structure of transistor structure 740 comprises a TMD layer which, for example, is a 2D material structure. Transistor structure 740 comprises one or more channel structures (e.g., one or more 2D materials each to provide a respective nanoribbon, nanowire or the like), and further comprises a gate electrode structure which surrounds some or all of the channel structures. For a given one of the channel structures, the transistor structure 740 further comprises a respective composite gate dielectric structure which surrounds said channel structure—e.g., wherein the composite gate dielectric structure is between that channel structure and the gate electrode structure. In an embodiment, the one such composite gate dielectric structure comprises two bodies of a first dielectric material, wherein the two bodies are at opposite respective edges of the channel structure. Furthermore, the composite gate dielectric structure comprises a layer of a second dielectric material which extends along (and adjoins) a side of the channel structure to each of the two bodies of the first dielectric material.

A gate of transistor structure 740, and source or drain (S/D) structures of transistor structure 740, are variously coupled (directly or indirectly) each to a respective one of interconnect metallization features 716—e.g., to facilitate operation of transistor structure 740 and/or signal communication with any of various other suitable circuit components which IC device 700 includes, or is to be coupled to.

In an embodiment, the FEOL circuit structures include one or more levels of interconnect metallization features 716 electrically insulated by dielectric materials 712 and 714. In the exemplary embodiment illustrated, the FEOL circuit structures include metal-one (M1), metal-two (M2), and metal-three (M3) interconnect metallization levels. Interconnect metallization features 716 are of any metal(s) suitable for FEOL and/or BEOL IC interconnection. Dielectric material 714 may have a different composition that dielectric material 712, and may be of a composition that has a higher dielectric constant than that of dielectric material 712. In some examples wherein dielectric material 712 is predominantly silicon and oxygen (i.e., SiOₓ), dielectric material 714 is predominantly silicon and nitrogen (i.e., SiNₓ). In other examples, where dielectric material 712 is a low-k dielectric (e.g., carbon-doped silicon oxide, SiOC:H), dielectric material 714 is predominantly a higher-k dielectric (e.g., SiO₂).

As further illustrated in FIG. 7, the BEOL circuit structures may further comprise any number of metallization levels, such as a metallization level (e.g., M5 and M6) above the metallization level (e.g., M4). Any number of interconnect metallization levels may couple BEOL circuitry 760 to the underlying the FEOL circuit structures. In the example shown in FIG. 7, metallization levels of BEOL circuitry (e.g., M6) may be routed down through any number of metallization levels (e.g., M5-M3) to be in electrical communication with one or more FEOL transistors 730.

In further embodiments, there may be multiple levels of the BEOL circuit structures located over the FEOL circuit structures, with dielectric material between each BEOL device circuitry level. A level of the BEOL circuit structures may include a plurality of PMOS and/or NMOS transistor structures, for example. In other embodiments, an IC structure includes multiple levels of the BEOL circuit structures without any monocrystalline FEOL transistors. For such embodiments, one or more levels of transistor structures may be over any of various suitable substrates (e.g., polymer, glass, etc.).

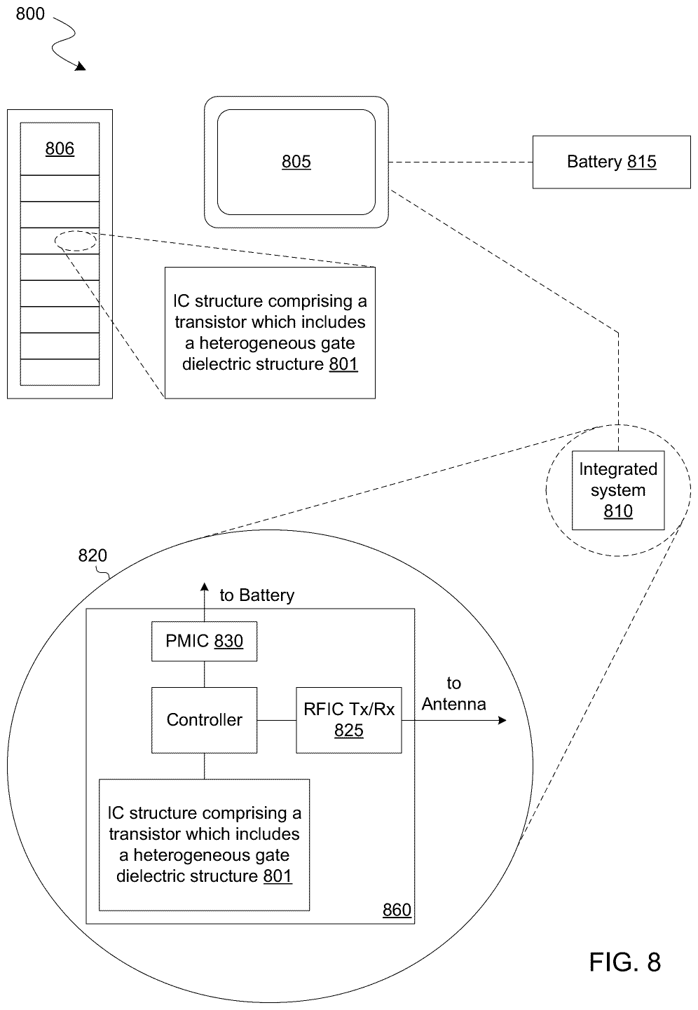

FIG. 8 illustrates a system 800 comprising a mobile computing platform 805 and a data server machine 806 employing a packaged IC die which include one or more metal chalcogenide transistors having gate dielectric structures, for example as described elsewhere herein. Server machine 806 may be any commercial server, for example including any number of high-performance computing platforms disposed within a rack and networked together for electronic data processing, which in the exemplary embodiment includes a packaged IC die comprising IC structure 801, for example as described elsewhere herein.

The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), an integrated system 810, and a battery 815.

As illustrated in the expanded view 820, another IC structure 801 is additionally or alternatively coupled to host component 860. One or more of a power management integrated circuit (PMIC) 830 or RF (wireless) integrated circuit (RFIC) 825 including a wideband RF (wireless) transmitter and/or receiver may be further coupled to host component 860. PMIC 830 may perform battery power regulation, DC-to-DC conversion, etc., and so has an input coupled to battery 815 and with an output providing a current supply to other functional modules. As further illustrated, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

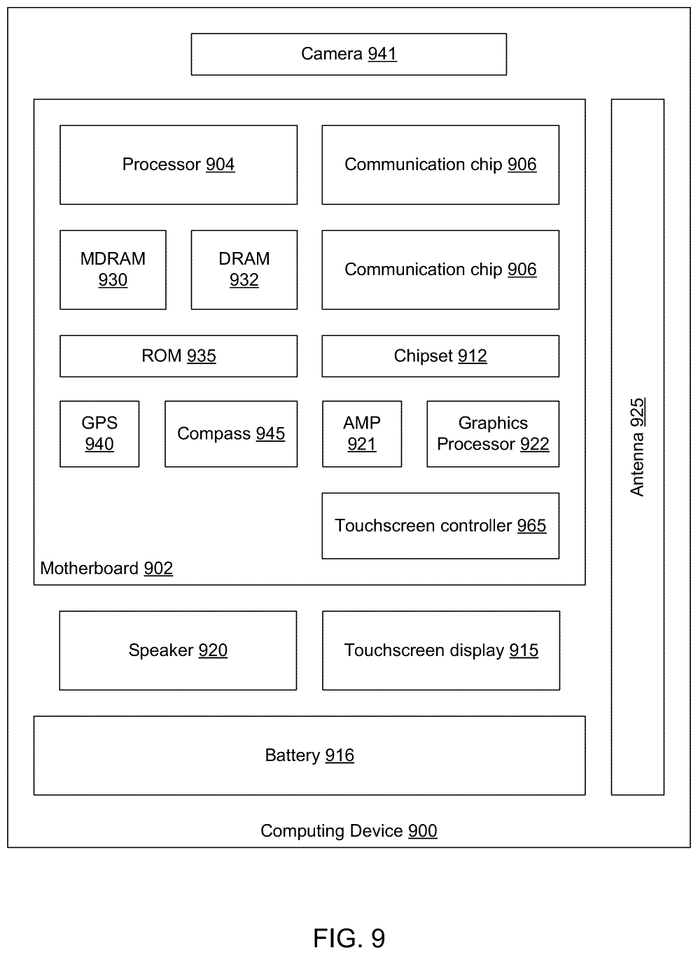

FIG. 9 is a functional block diagram of an electronic computing device 900, in accordance with some embodiments. Device 900 further includes a motherboard 902 hosting a number of components, such as, but not limited to, a processor 904 (e.g., an applications processor). Processor 904 may be physically and/or electrically coupled to motherboard 902. In some examples, processor 904 comprises circuit structures which, for example, are described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 906 may also be physically and/or electrically coupled to the motherboard 902. In further implementations, communication chips 906 may be part of processor 904. Depending on its applications, computing device 900 may include other components that may or may not be physically and electrically coupled to motherboard 902. These other components include, but are not limited to, volatile memory (e.g., DRAM 932), non-volatile memory (e.g., ROM 935), flash memory (e.g., NAND or NOR), magnetic memory (MRAM) 930, a graphics processor 922, a digital signal processor, a crypto processor, a chipset 912, an antenna 925, touchscreen display 915, touchscreen controller 965, battery 916, audio codec, video codec, power amplifier (AMP) 921, global positioning system (GPS) device 940, compass 945, accelerometer, gyroscope, speaker 920, camera 941, and mass storage device (such as hard disk drive, solid-state drive (SSD), compact disk (CD), digital versatile disk (DVD), and so forth, or the like.

Communication chips 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 906 may implement any of a number of wireless standards or protocols, including, but not limited to, those described elsewhere herein. As discussed, computing device 900 may include a plurality of communication chips 906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

The description herein sets forth numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Techniques and architectures for providing transistor structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

In one or more first embodiments, a transistor structure comprises a channel structure comprising a layer of a transition metal dichalcogenide (TMD) material, the channel structure comprising a first surface and a second surface at opposite respective sides of the channel structure, a first gate dielectric structure at a first edge of the channel structure, a second gate dielectric structure at a second edge of the channel structure, wherein the first gate dielectric structure and the second gate dielectric structure each comprise a first dielectric material, wherein first gate dielectric structure and the second gate dielectric structure each extend to both the first surface and the second surface a third gate dielectric structure adjacent to the first surface, the third gate dielectric structure comprising a second dielectric material, wherein the third gate dielectric structure extends to each of the first gate dielectric structure and the second gate dielectric structure, a gate electrode structure which surrounds the channel structure, the first gate dielectric structure, the second gate dielectric structure, and the third gate dielectric structure, and a first source or drain (S/D) electrode structure and a second S/D electrode structure at opposite respective ends of the channel structure.

In one or more second embodiments, further to the first embodiment, a first dielectric constant of the first dielectric material is less than a second dielectric constant of the second dielectric material.

In one or more third embodiments, further to the first embodiment or the second embodiment, the first gate dielectric structure extends horizontally to partially cover the first surface.

In one or more fourth embodiments, further to the third embodiment, a horizontal thickness of the first gate dielectric structure at the first edge is greater than a vertical thickness of the first gate dielectric structure from the first surface.

In one or more fifth embodiments, further to the fourth embodiment, a width of the channel structure, between the first edge and the second edge, is in a range of 5 nanometers (nm) to 10 nm, the horizontal thickness is in a range of 4 nm to 8 nm, and wherein the vertical thickness is in a range of 2 nm to 4 nm.

In one or more sixth embodiments, further to the third embodiment, the first gate dielectric structure further extends horizontally to partially cover the second surface.

In one or more seventh embodiments, further to the first embodiment or the second embodiment, the channel structure is a monolayer of the TMD material.

In one or more eighth embodiments, further to the first embodiment or the second embodiment, the third gate dielectric structure further adjoins the second surface, wherein the third gate dielectric structure extends along the second surface to each of the first gate dielectric structure and the second gate dielectric structure.

In one or more ninth embodiments, further to the eighth embodiment, the third gate dielectric structure extends around the first gate dielectric structure and the second gate dielectric structure.

In one or more tenth embodiments, further to the eighth embodiment, the channel structure is surrounded by the first gate dielectric structure and the second gate dielectric structure.

In one or more eleventh embodiments, a method comprises forming a channel structure which comprises a layer of a transition metal dichalcogenide (TMD) material, the channel structure comprising a first surface and a second surface at opposite respective sides of the channel structure, forming a first gate dielectric structure and a second gate dielectric structure at a first edge and a second edge, respectively, of the channel structure, wherein the first gate dielectric structure and the second gate dielectric structure each comprise a first dielectric material, and wherein first gate dielectric structure and the second gate dielectric structure each extend to both the first surface and the second surface forming a third gate dielectric structure adjacent to the first surface, wherein the third gate dielectric structure comprises a second dielectric material, and wherein the third gate dielectric structure extends to each of the first gate dielectric structure and the second gate dielectric structure, forming a gate electrode structure which surrounds the channel structure, and forming a first source or drain (S/D) electrode structure and a second S/D electrode structure at opposite respective ends of the channel structure.

In one or more twelfth embodiments, further to the eleventh embodiment, a first dielectric constant of the first dielectric material is less than a second dielectric constant of the second dielectric material.

In one or more thirteenth embodiments, further to the eleventh embodiment or the twelfth embodiment, the first gate dielectric structure extends horizontally to partially cover the first surface.

In one or more fourteenth embodiments, further to the thirteenth embodiment, a horizontal thickness of the first gate dielectric structure at the first edge is greater than a vertical thickness of the first gate dielectric structure from the first surface.

In one or more fifteenth embodiments, further to the fourteenth embodiment, a width of the channel structure, between the first edge and the second edge, is in a range of 5 nanometers (nm) to 10 nm, the horizontal thickness is in a range of 4 nm to 8 nm, and wherein the vertical thickness is in a range of 2 nm to 4 nm.

In one or more sixteenth embodiments, further to the thirteenth embodiment, the first gate dielectric structure further extends horizontally to partially cover the second surface.

In one or more seventeenth embodiments, further to the eleventh embodiment or the twelfth embodiment, the channel structure is a monolayer of the TMD material.

In one or more eighteenth embodiments, further to the eleventh embodiment or the twelfth embodiment, the third gate dielectric structure further adjoins the second surface, wherein the third gate dielectric structure extends along the second surface to each of the first gate dielectric structure and the second gate dielectric structure.

In one or more nineteenth embodiments, further to the eighteenth embodiment, the third gate dielectric structure extends around the first gate dielectric structure and the second gate dielectric structure.

In one or more twentieth embodiments, further to the eighteenth embodiment, the channel structure is surrounded by the first gate dielectric structure and the second gate dielectric structure.

In one or more twenty-first embodiments, an integrated circuit (IC) comprises a first nanoribbon comprising a first layer of a transition metal dichalcogenide (TMD) material, first portions of a first dielectric material at opposite respective first edges of the first nanoribbon, a second portion of a second dielectric material adjacent to the first portions and adjacent to first surfaces at opposite respective sides of the first nanoribbon, a second nanoribbon comprising a second layer of the TMD material, third portions of the first dielectric material at opposite respective second edges of the second nanoribbon, a fourth portion of the second dielectric material adjacent to the third portions and adjacent to second surfaces at opposite respective sides of the second nanoribbon, a first source or drain (S/D) electrode structure and a second S/D electrode structure, wherein the first nanoribbon and the second nanoribbon each extend between the first S/D electrode structure and the second S/D electrode structure, and a gate electrode structure between the first S/D electrode structure and the second S/D electrode structure, wherein the gate electrode structure surrounds the first nanoribbon and the second nanoribbon.

In one or more twenty-second embodiments, further to the twenty-first embodiment, a first dielectric constant of the first dielectric material is less than a second dielectric constant of the second dielectric material.

In one or more twenty-third embodiments, further to the twenty-first embodiment or the twenty-second embodiment, the first portions extend horizontally to partially cover the first surfaces.

In one or more twenty-fourth embodiments, further to the twenty-third embodiment, a horizontal thickness of one of the first portions at one of the first edges is greater than a vertical thickness of the one of the first portions from one of the first surfaces.

In one or more twenty-fifth embodiments, further to the twenty-fourth embodiment, a width of the first nanoribbon, between the first edges, is in a range of 5 nanometers (nm) to 10 nm, the horizontal thickness is in a range of 4 nm to 8 nm, and wherein the vertical thickness is in a range of 2 nm to 4 nm.

In one or more twenty-sixth embodiments, further to the twenty-first embodiment or the twenty-second embodiment, the TMD material is a monolayer of the TMD material.

In one or more twenty-seventh embodiments, further to the twenty-first embodiment or the twenty-second embodiment, the second portion surrounds the first portions.

In one or more twenty-eighth embodiments, further to the twenty-seventh embodiment, the fourth portion surrounds the second portions.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A transistor structure comprising:
a channel structure comprising a layer of a transition metal dichalcogenide (TMD) material, the channel structure comprising a first surface and a second surface at opposite respective sides of the channel structure;
a first gate dielectric structure at a first edge of the channel structure;
a second gate dielectric structure at a second edge of the channel structure, wherein the first gate dielectric structure and the second gate dielectric structure each comprise a first dielectric material, wherein first gate dielectric structure and the second gate dielectric structure each extend to both the first surface and the second surface;
a third gate dielectric structure adjacent to the first surface, the third gate dielectric structure comprising a second dielectric material, wherein the third gate dielectric structure extends to each of the first gate dielectric structure and the second gate dielectric structure;
a gate electrode structure which surrounds the channel structure, the first gate dielectric structure, the second gate dielectric structure, and the third gate dielectric structure; and
a first source or drain (S/D) electrode structure and a second S/D electrode structure at opposite respective ends of the channel structure.

2. The transistor structure of claim 1, wherein a first dielectric constant of the first dielectric material is less than a second dielectric constant of the second dielectric material.

3. The transistor structure of claim 1, wherein the first gate dielectric structure extends horizontally to partially cover the first surface.

4. The transistor structure of claim 3, wherein a horizontal thickness of the first gate dielectric structure at the first edge is greater than a vertical thickness of the first gate dielectric structure from the first surface.

5. The transistor structure of claim 4, wherein:
a width of the channel structure, between the first edge and the second edge, is in a range of 5 nanometers (nm) to 10 nm;
the horizontal thickness is in a range of 4 nm to 8 nm; and
wherein the vertical thickness is in a range of 2 nm to 4 nm.

6. The transistor structure of claim 3, wherein the first gate dielectric structure further extends horizontally to partially cover the second surface.

7. The transistor structure of claim 1, wherein the channel structure is a monolayer of the TMD material.

8. The transistor structure of claim 1, wherein the third gate dielectric structure further adjoins the second surface, wherein the third gate dielectric structure extends along the second surface to each of the first gate dielectric structure and the second gate dielectric structure.

9. The transistor structure of claim 8, wherein the third gate dielectric structure extends around the first gate dielectric structure and the second gate dielectric structure.

10. The transistor structure of claim 8, wherein the channel structure is surrounded by the first gate dielectric structure and the second gate dielectric structure.

11. A method comprising:
forming a channel structure which comprises a layer of a transition metal dichalcogenide (TMD) material, the channel structure comprising a first surface and a second surface at opposite respective sides of the channel structure;
forming a first gate dielectric structure and a second gate dielectric structure at a first edge and a second edge, respectively, of the channel structure, wherein the first gate dielectric structure and the second gate dielectric structure each comprise a first dielectric material, and wherein first gate dielectric structure and the second gate dielectric structure each extend to both the first surface and the second surface;
forming a third gate dielectric structure adjacent to the first surface, wherein the third gate dielectric structure comprises a second dielectric material, and wherein the third gate dielectric structure extends to each of the first gate dielectric structure and the second gate dielectric structure;
forming a gate electrode structure which surrounds the channel structure; and
forming a first source or drain (S/D) electrode structure and a second S/D electrode structure at opposite respective ends of the channel structure.

12. The method of claim 11, wherein a first dielectric constant of the first dielectric material is less than a second dielectric constant of the second dielectric material.

13. The method of claim 11, wherein the first gate dielectric structure extends horizontally to partially cover the first surface.

14. The method of claim 11, wherein the channel structure is a monolayer of the TMD material.

15. The method of claim 11, wherein the third gate dielectric structure further adjoins the second surface, wherein the third gate dielectric structure extends along the second surface to each of the first gate dielectric structure and the second gate dielectric structure.

16. An integrated circuit (IC) comprising:
a first nanoribbon comprising a first layer of a transition metal dichalcogenide (TMD) material;
first portions of a first dielectric material at opposite respective first edges of the first nanoribbon;
a second portion of a second dielectric material adjacent to the first portions and adjacent to first surfaces at opposite respective sides of the first nanoribbon;
a second nanoribbon comprising a second layer of the TMD material;
third portions of the first dielectric material at opposite respective second edges of the second nanoribbon;
a fourth portion of the second dielectric material adjacent to the third portions and adjacent to second surfaces at opposite respective sides of the second nanoribbon;
a first source or drain (S/D) electrode structure and a second S/D electrode structure, wherein the first nanoribbon and the second nanoribbon each extend between the first S/D electrode structure and the second S/D electrode structure; and
a gate electrode structure between the first S/D electrode structure and the second S/D electrode structure, wherein the gate electrode structure surrounds the first nanoribbon and the second nanoribbon.

17. The IC of claim 16, wherein a first dielectric constant of the first dielectric material is less than a second dielectric constant of the second dielectric material.

18. The IC of claim 16, wherein the first portions extend horizontally to partially cover the first surfaces.

19. The IC of claim 16, wherein the TMD material is a monolayer of the TMD material.

20. The IC of claim 16, wherein the second portion surrounds the first portions.
